(19) United States
(12) Patent Application Publication
(10) Pub. No.: US 2026/0286503 A1
(43) Pub. Date: Sep. 24, 2026

(54) VAPOUR DEPOSITION DEVICE AND METHOD OF DEPOSITING A MATERIAL LAYER ONTO A SUBSTRATE

(71) Applicant: Demcon TSST B.V., ENSCHEDE (NL)

(72) Inventors: Emiel Daniël RUTGERS, ENSCHEDE (NL); Augustinus Josephus Helena M. RIJNDERS, VRAGENDER (NL); Gertjan KOSTER, ENSCHEDE (NL)

(73) Assignee: Demcon TSST B.V., ENSCHEDE (NL)

(21) Appl. No.: 19/477,156

(22) PCT Filed: Apr. 29, 2024
(86) PCT No.: PCT/NL2024/050222

§ 371 Date: Oct. 21, 2025

(30) Foreign Application Priority Data
Apr. 28, 2023 (NL) 2034725

(51) Int. Cl. C23C 14/28; C23C 14/04; C23C 14/50

(52) U.S. Cl. CPC C23C 14/28; C23C 14/042; C23C 14/505

(57) ABSTRACT

A vapour deposition device for depositing a material layer onto a substrate, in particular a pulsed laser deposition device, the device comprises: a substrate holder comprising a substrate holding surface for holding a material deposition substrate thereon; a target holder for holding a source of material to be deposited onto the substrate held on the substrate holding surface; and a vaporisation unit for directing a vaporising beam to the target holder to vaporise, at a beam end, a portion of the material source for the vaporised portion to be deposited onto the substrate held on the substrate holding surface, wherein the device is arranged to relatively move the beam end relative to the target holder in at least two nonparallel directions, and wherein the device is arranged to relatively move the target holder relative to the substrate holding surface in a direction which is non-perpendicular to the substrate holding surface.

The present invention relates to a vapour deposition device for, and a method of, depositing a material layer onto a substrate.

Deposition is a technique for forming a thin film on a substrate. For example, in pulsed laser deposition (PLD) which is often performed inside a vacuum chamber in, e.g., the presence of a background gas such as high-purity oxygen or argon, a pulsed laser beam is directed to a target of material, such as a sintered or compressed target material, and vaporises the material to create a plasma plume. The vaporised material condenses as a thin film on a substrate facing the target. As the material particles bind to the surface, they grow into islands which merge into a thin material layer.

One of the factors that influence the deposition of the material layer is the temperature of the substrate. Specifically, the substrate surface temperature affects the nucleation density. The substrate may be heated on a heating plate to enhance a property of the thin film, such as crystallinity, for an improved quality.

A known problem is that cracking of the target material can occur in case a target material of low thermal conductivity is heated. In current systems, such as disclosed in European patent No. 2 243 856, a heat shield is arranged between the substrate and the target for shielding the target from being heated by the heated substrate. The heat shield is cooled to prevent the target from being heated via the heat shield. A drawback is that the current systems are energy intensive.

A further known problem with heating substrates, particularly large substrates, is that also heat-sensitive components of the system may reach critical temperatures.

It is therefore an object of the present invention, amongst other objects, to provide a vapour deposition device, in particular an efficient vapour deposition device, wherein the aforesaid drawbacks are at least partially alleviated.

Hereto, according to a first aspect of the present invention, a vapour deposition device for depositing a material layer onto a substrate is provided, in particular a pulsed laser deposition device, wherein the vapour deposition device comprises a substrate holder comprising a substrate holding surface for holding a material deposition substrate thereon, a target holder for holding a source of material to be deposited onto the substrate held on the substrate holding surface, and a vaporisation unit arranged for directing a vaporising beam to the target holder to vaporise, at a beam end where the vaporising beam hits the material source held by the target holder, a portion of the material source for the vaporised portion to be deposited onto the substrate held on the substrate holding surface, wherein the device is arranged to relatively move the beam end relative to the target holder in at least two nonparallel directions for scanning the beam end over an area of the material source, and wherein the device is arranged to relatively move the target holder relative to the substrate holding surface in a direction which is non-perpendicular to the substrate holding surface.

By moving the target holder relative to the substrate holding surface, preferably in a direction which is non-perpendicular to the substrate holding surface, a target held by the target holder can be moved relative to a substrate held on the substrate holding surface, such that the material can be deposited over a substrate area that is larger than the area of the target. Consequently, a relatively small target can be used. It has been found that reducing the target size reduces the risk of target cracking, since relatively large targets can be more difficult to produce in a high density and may consequently be more prone to cracking. Thereby, in the aforesaid case wherein a shield is arranged between the substrate and the target and is cooled to prevent the target from being heated, the energy use for cooling can be reduced. Hence, an energy efficient vapour deposition device can be provided. Moreover, as the shield is cooled less, the substrate heater can similarly maintain a temperature of the substrate using less power, which can reduce the maximum temperature in the system overall.

Preferably, the device is arranged to translate the target holder relative to the substrate holding surface in the direction that is non-perpendicular to the substrate holding surface. By translating the target holder, a relatively small target can be efficiently moved relative to the substrate for depositing the material over a relatively large area of the substrate. For moving the target holder relative to the substrate holding surface, the device may comprise a target holder moving mechanism, such as a target holder positioning system or the like, wherein the target holder moving mechanism is arranged to move the target holder relative to the substrate holding surface. The target holder moving mechanism may comprise at least one, preferably two, target holder positioners arranged to move the target holder in at least one, preferably both, of the two nonparallel directions.

The vapour deposition device may comprise a housing with a chamber for creating a vacuum chamber to provide suitable process conditions, wherein the substrate holder and the target holder are arranged in the chamber.

When holding the material source spaced from the substrate and/or the substrate holding surface, the target holder may be arranged for holding the material source, in particular its surface, parallel to the substrate and/or the substrate holding surface, in particular to a surface of the substrate. In general, it is preferred if the target holder is arranged for holding the material source facing the substrate holding surface and/or the substrate held thereon. It is further preferred if the direction of the vaporising beam is nonparallel to the substrate surface or the substrate holding surface.

The vaporisation unit may be a laser unit, wherein the vaporising beam is a laser beam. To move the beam end relative to the target holder and/or the material source held thereby, the vaporisation unit may be arranged to move the vaporising beam over the target. The beam end is moved, preferably translated, over the surface of the material source in the at least two directions that are mutually nonparallel, preferably orthogonal. If the surface of the material source is parallel to the substrate surface as described above, said at least two directions are thus also parallel to the substrate surface. The at least two nonparallel directions extend in a target plane that corresponds to the surface of the material source and is, in particular, coplanar therewith. In other words, the device is arranged to move the beam end relative to the target holder in the target plane for scanning the beam end over an area of the material source. By moving the vaporising beam over the target in the at least two nonparallel directions or at least two degrees of freedom, the beam end can be scanned over an entire area of the material source, for instance in the at least two nonparallel directions. Scanning the beam end over the target in the at least two nonparallel directions can thus for instance be achieved by moving the vaporising beam in one of the two directions and moving the target in at least the other of the two directions. As the material source can be used more efficiently, a smaller target can be used such that a more efficient vapour deposition device can be provided.

The direction in which the target holder is moved relative to the substrate holding surface and which is non-perpendicular to the substrate or the substrate holding surface, is preferably parallel to the substrate surface or the substrate holding surface.

By moving the beam end relative to the substrate or the substrate holding surface, a plume of vaporised material is generated which moves relative to the substrate or the substrate holding surface such that the material can be deposited onto a relatively large substrate area, i.e., a substrate area that is larger than the extent of the plume.

According to a preferred embodiment of the vapour deposition device, the substrate holding surface is rotatable about a substrate axis, which extends therethrough and is perpendicular thereto, for axially rotating the substrate held on the substrate holding surface. By rotating the substrate holder in this manner, forming a large area thin film can be facilitated. Preferably, the vaporisation unit is arranged to translate the beam end towards and away from the substrate axis. That is, the beam end may be reciprocated in a direction traverse to the substrate axis such that, as the substrate holding surface rotates, the material can be deposited onto the entire substrate surface.

The target holder may be movable relative to the substrate holding surface in the same direction in which the beam end is moved relative to the target holder. As such, the device may be arranged to translate the target holder relative to the substrate holding surface in at least one of the two nonparallel directions. Preferably, the device is arranged to translate the target holder relative to the substrate holding surface in one or both of the two nonparallel directions, i.e., a direction parallel to one or both of said two directions.

According to a second aspect, a vapour deposition device for depositing a material layer onto a substrate is provided, preferably according to any of the above embodiments, wherein the vapour deposition device comprises a substrate holder comprising a substrate holding surface for holding a material deposition substrate thereon, a target holder for holding a source of material to be deposited onto the substrate held on the substrate holding surface, and a vaporisation unit arranged for directing a vaporising beam to the target holder to vaporise, at a beam end where the vaporising beam hits the material source held by the target holder, a portion of the material source for the vaporised portion to be deposited onto the substrate held on the substrate holding surface, wherein the vapour deposition device further comprises a shield member arranged between the target holder and the substrate holding surface, wherein the shield member is provided with a passage opening therethrough for the vaporised material to pass through the shield member and to be deposited onto the substrate held on the substrate holding surface. In particular, the vapour deposition device may be a pulsed laser deposition device.

As aforementioned, a vapour deposition device generally comprises a substrate heater for heating the substrate. The shield member is then arranged between the substrate and the target for shielding the target from being heated by the substrate heater. The shield member may be plate-like and is preferably arranged parallel to the substrate holding surface and/or the substrate surface.

The vapour deposition device may further comprise a shield heating system arranged to maintain a temperature of the shield member within a first predetermined range of, e.g., 400 to 1300 kelvins, preferably 450 to 1100 kelvins. Hereto, the shield heating system may comprise, e.g., at least one heating element integrated into the shield member. Via the heated shield member, the substrate can be additionally heated, albeit indirectly, in addition to being heated by the substrate holder heater. It has been found that, by heating the shield member instead of cooling, the overall energy efficiency of the system could be enhanced to an unforeseeable extent. By additionally heating the substrate via the shield member, the temperature of the substrate holder heater can be reduced, which can reduce the maximum temperature in the system overall, which reduces the risk of target cracking.

Furthermore, it has been found that, by heating the shield member, the influence of temperature on the plume of vaporised material can be reduced.

According to a preferred embodiment of the vapour deposition device, the device is arranged to translate the beam end relative to the substrate holding surface in a direction which is non-perpendicular, preferably parallel, to the substrate holding surface. It is then further preferred if the shield member is movable relative to the substrate holding surface along with the beam end for translating the passage opening synchronously with the beam end. This way, the passage opening for the vaporised material follows the beam end where the plume is generated. Preferably, the shield member is moved parallel to the substrate surface or the substrate holding surface.

For moving the shield member relative to the substrate holding surface, the device may comprise a shield member moving mechanism, such as a shield member positioning system or the like, wherein the shield member moving mechanism is arranged to move the shield member relative to the substrate holding surface. The shield member moving mechanism may comprise a shield member positioner arranged to move the shield member in at least one of the two nonparallel directions. In general, the passage opening is to remain aligned with the plume, essentially in correspondence with the beam end. That is, the shield member, in particular the passage opening, is arranged to move synchronously with the beam end.

As noted above, the vapour deposition device may further comprise a holder heating system arranged to maintain a temperature of the substrate holder, in particular of the substrate holding surface, in a second predetermined range of, e.g., 290 to 1400 kelvins, preferably 400 to 1300 kelvins. It is then preferred if said temperature of the substrate holder exceeds said temperature of the shield member.

The plume of vaporised material may have nonuniform particle sizes. Relatively large particulates may contaminate the thin film, alter its properties and degrade its quality. In general, the plume has large particulates in its periphery. The outer side part of the plume, which includes said large particulates, can be blocked by the shield member, in particular the edge around the passage opening, to prevent the large particulates from being deposited onto the substrate. To that end, the passage opening can be sized accordingly and is, for instance, a pinhole or of similar shape, preferably circular. The diameter of the passage opening may be in the range of 1 to 40 millimetres, preferably 5 to 30. As such, the passage opening in the shield member can be dimensioned such that the edges of the passage opening block the sides of an inhomogeneous plasma plume such that only the centre part of the plasma plume is deposited onto the substrate.

However, also in the centre part of the plume large particulates are present, which may pass through the passage opening of the shield member and degrade the quality of the thin film. To prevent the large particulates in the centre part from being deposited onto the substrate, according to a further preferred embodiment of the vapour deposition device, the device further comprises a shadow mask element arranged stationary relative to the shield member and between the passage opening and the target holder to deflect the vaporised material. In other words, the shadow mask element is arranged in front of the passage opening as seen from the target holder. More specifically, the shadow mask element blocks the passage opening from the line of sight as seen from the beam end.

By placing the shadow mask element between the passage opening and the target holder, the shadow mask element is located in, and thereby blocks, the centre of the plume such that the smaller, lighter particles in the plume diffuse around the shadow mask element whereas the larger, heavier particulates are deflected out of the centre by the shadow mask element and blocked by the shield member.

It has been found that a shadow mask element having a flat surface parallel to and facing the target material may cause the particles to bounce back and disturb the plume. Therefore, the shadow mask element may be tapered towards the target holder. For instance, the shadow mask element may be conical, to effectively deflect the particulates without causing the particles to bounce back. Additionally, or alternatively, the shadow mask element may be tapered towards the passage opening. More in general, the side of the shadow mask element that faces the passage opening is preferably not flat. This portion of the shadow mask element is then shaped to create a low-pressure region for the plume downstream of the shadow mask element, i.e., between the shadow mask element and the passage opening. This way, the plume particles, in particular the lighter particles, converge again after passing the shadow mask element.

According to a further preferred embodiment of the vapour deposition device, the shadow mask element is droplet shaped, more specifically teardrop shaped. This way, the pressure gradient around the shadow mask element can be improved, as the plume can propagate around the shadow mask element more smoothly.

The pointy end of the droplet-shaped shadow mask element may point to the passage opening or to the target holder. The side opposite to the side with the pointy end may be provided with a conical protrusion pointing in a direction opposite to the pointy end of the droplet-shaped shadow mask element.

According to yet another aspect, a method of depositing a material layer onto a substrate is provided, wherein the method comprises the steps of:
providing a material deposition substrate;
providing a source of material to be deposited onto the substrate;
directing a vaporising beam to the material source to vaporise, at a beam end where the vaporising beam hits the material source, a portion of the material source;
moving the beam end relative to the material source in at least two nonparallel directions for scanning the beam end over an area of the material source;
depositing the vaporised material onto the substrate;
moving, preferably translating, the material source relative to the substrate in a direction which is non-perpendicular to the substrate.

The method may comprise the step of providing a vapour deposition device according to any of the embodiments described herein, wherein the substrate holder holds the substrate on the substrate holding surface, wherein the target holder holds the material source, and wherein the vaporising beam is directed to the material source using the vaporisation unit.

The method preferably further comprises the step of axially rotating the substrate about a substrate axis which extends therethrough and is perpendicular to a surface of the substrate facing the material source.

The step of vaporising the portion of the material source preferably comprises translating the beam end towards and away from the substrate axis. That is, the beam end may be reciprocated in a direction traverse to the substrate axis such that, as the substrate rotates, the material can be deposited onto the entire substrate surface.

Preferably, the method further comprises the step of translating the material source relative to the substrate in one or both of the two nonparallel directions.

According to yet another aspect, a method of depositing a material layer onto a substrate is provided, preferably according to the method as described above, wherein the method comprises the steps of:
providing a material deposition substrate;
providing a source of material to be deposited onto the substrate;
providing a shield member between the material source and the substrate, wherein the shield member is provided with a passage opening therethrough for the vaporised material to pass through the shield member and be deposited onto the substrate;
directing a vaporising beam to the material source to vaporise, at a beam end where the vaporising beam hits the material source, a portion of the material source;
depositing the vaporised material onto the substrate.

The method preferably further comprises the steps of:
translating the beam end relative to the substrate in a direction which is non-perpendicular to the substrate;
moving the shield member relative to the substrate along with the beam end for translating the passage opening synchronously with the beam end.

Preferably, the method further comprises the step of maintaining a temperature of the shield member within a first predetermined range.

The method preferably further comprises the step of maintaining a temperature of the substrate in a second predetermined range. Preferably, the temperature of the substrate exceeds the temperature of the shield member.

The method may comprise the step of providing a vapour deposition device according to any of the embodiments described herein, wherein the substrate is held on the substrate holding surface of the vapour deposition device, wherein the material source is held by the target holder of the vapour deposition device, and wherein the portion of the material source is vaporised using the vaporisation unit of the vapour deposition device.

The present invention is further elucidated with reference to the attached drawings, wherein:

FIG. 1 schematically depicts a first embodiment of a vapour deposition device;

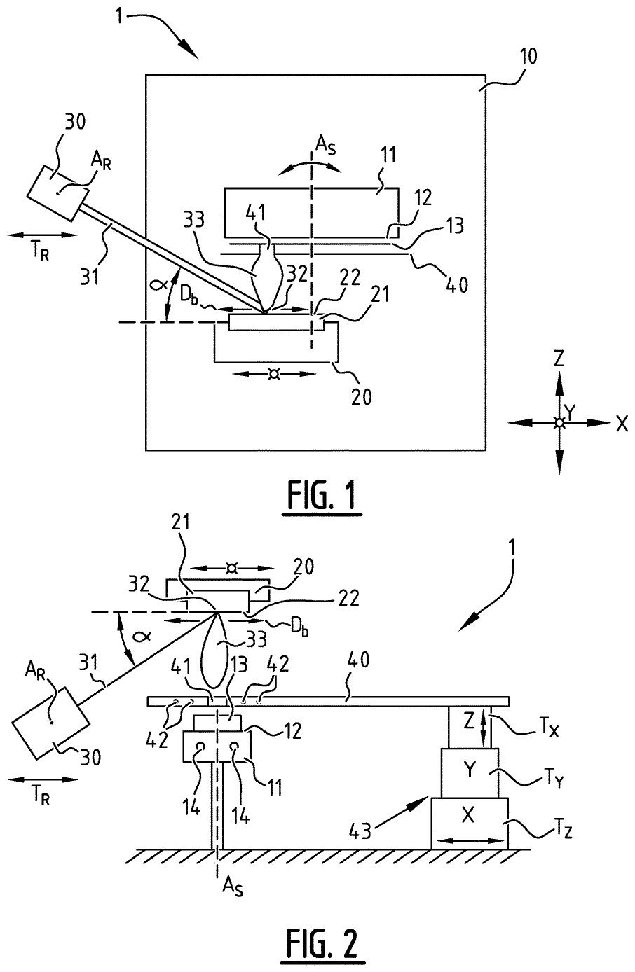

FIG. 2 schematically depicts a second embodiment of a vapour deposition device;

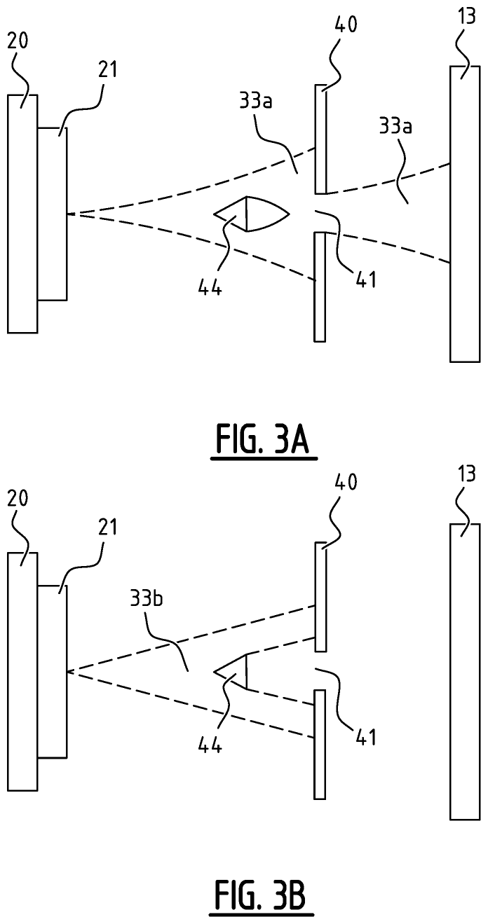

FIGS. 3A and 3B schematically depict an arrangement of a shield and a shadow mask;

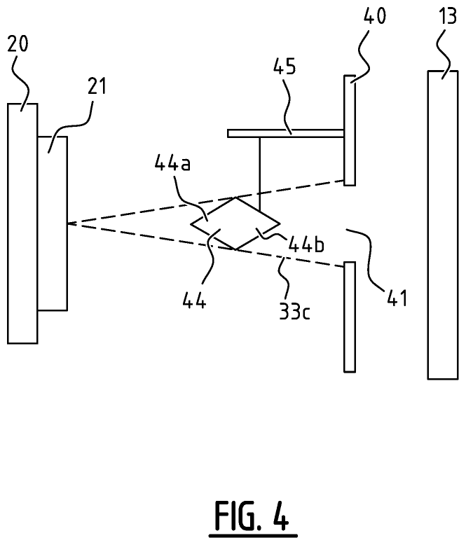

FIG. 4 schematically depicts an arrangement of a shield and an alternative shadow mask;

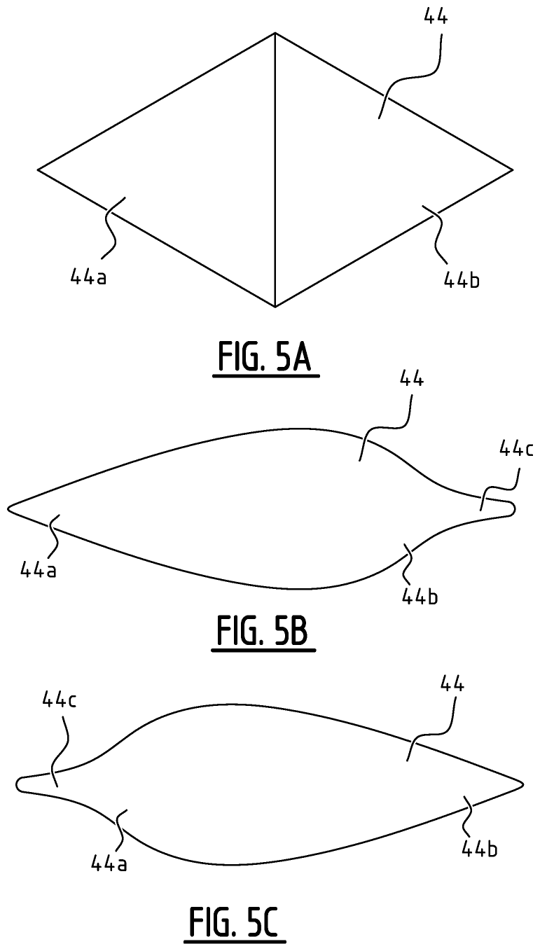

FIGS. 5A, 5B and 5C depict various embodiments of the shadow mask.

In the drawings of the different embodiments, like elements are indicated by like reference signs.

FIG. 1 shows a schematic side view of the vapour deposition device 1, specifically a large-area pulsed laser deposition device. The device 1 comprises a substrate holder 11 that comprises a substrate holding surface 12 on which a substrate 13 is held. The substrate holder 11 is rotatable around an axis As perpendicular to the holding surface 12. The substrate holder 11 may alternatively, or additionally, translate in two perpendicular directions perpendicular to the axis Aₛ, herein referred to as the xy-plane, and optionally also translate in the direction parallel to the axis Aₛ, herein referred to as the z-direction.

The vapour deposition device 1 additionally comprises a target holder 20 holding a source of material 21 (also referred to as the “target” 21) to be deposited onto the substrate 13 held on the substrate holding surface 12. The source of material 21 comprises a substantially planar target surface 22 parallel to and facing the substrate 13. The target holder 20 is translated in two orthogonal directions in the xy-plane or, alternatively or additionally, may be rotatable around two or three substantially mutually perpendicular axes, such that the entire target surface 22 can be scanned as described in the following.

The vapour deposition device 1 additionally comprises a vaporisation unit 30, specifically a laser unit, arranged for directing a vaporising laser beam 31 to the target holder 20, in particular the target surface 22, to vaporise, at beam end 32, a portion of the source material 21. The vaporising beam 31 may travel towards the target holder 20 at an angle of incidence a relative to the target surface 22. The angle of incidence a is between 30° and 60°, preferably between 40° and 50°, more preferably about 45°. This vaporisation of a portion of the target surface 22 creates a vaporised portion 33, also referred to as a plasma plume 33. This plume 33 travels in a direction substantially perpendicular to the target surface 22 towards the substrate 13. The vaporisation unit 30 is arranged to translate the beam end 32 in the x-direction perpendicular to the substrate axis Aₛ in a reciprocating manner as indicated by the arrows D_{b} in the figure. This translation of the beam end 32 can be achieved by rotating the vaporisation unit 30 around the axis A_{R} perpendicular to the vaporising beam 31. This method of translating the beam end 32 changes the angle of incidence a as the beam end 32 translates. Alternatively, the beam end 32 may be translated by translating the vaporising unit 30 in one or more of the three spatial dimensions, or three mutually perpendicular directions, one of which being the x-direction as indicated by the arrow T_{R}. This method of translating maintains a constant angle of incidence α.

The vapour deposition device 1 further comprises a shield member 40, arranged between the target holder 20 and the substrate holding surface 12. This shield member 40 is provided with a passage opening 41 for part of the plume 33, specifically the centre part, to pass through the shield member 40 to be deposited on the substrate 13 held on the substrate holding surface 12. The shield member 40 is translated parallel to the substrate holding surface in the x-direction along with the beam end 32 for translating the passage opening 41 synchronously with the beam end 32.

The substrate holder 11, the target holder 20, and the shield 40 are installed in a vacuum chamber 10 of the device 1. The pulsed laser deposition is preferably performed in a high-purity oxygen or argon background pressure.

FIG. 2 shows a schematic side view of another embodiment of the vapour deposition device 1.

The shield member 40 is mounted on shield holder 43 that comprises a motion mechanism comprising positioners T_{X}, T_{Y}, and T_{Z}. The shield member 40 is translatable in three mutually perpendicular directions by the positioners T_{X}, T_{Y}, and T_{Z}. Alternatively, particularly in an embodiment wherein the substrate 13 is axially rotated about its axis Aₛ, it is possible that the shield member 40 is only translated in the x-direction perpendicular to the substrate axis Aₛ in a reciprocating manner for the passage opening 41 to follow the beam end 32. The shield member 40 additionally comprises a shield heating system 42 which is arranged to heat the shield member 40 and maintain the shield member 40 at a predefined temperature. The shield heating system 42 hereto comprises heating elements 42 that are integrated in the shield member 40.

The substrate holder 11 additionally comprises a holder heating system 14 arranged to heat the substrate holder 11 and maintain the substrate holder 11 at a temperature. The holder heating system 14 hereto comprises holder heating elements 14 that are integrated in the substrate holder 11. The same may be applied for the substrate holder 11 and the shield 40 in the embodiment shown in FIG. 1.

FIGS. 3A and 3B show a detailed view of the target holder 20, target 21, the plume 33, the shield 40, and the substrate 13. In this embodiment, the shield 40 is combined with a shadow mask element 44 which is arranged stationary relative to the shield 40, and between the passage opening 41 and the target holder 20. The effect of the shadow mask element 44 on the plume 33 is illustrated as follows. The plume 33 comprises particles that have a different mass. FIG. 3A indicates, by means of dashed lines, the path of the lighter plume constituents 33a diffusing around the shadow mask 44. FIG. 3B indicates, by means of dashed lines, the path of the heavier plume constituents 33b. The large particulates 33b generally propagate in a straight line and can thus be fully blocked, partially by the shield 40 directly, and partially by the shadow mask 44 and subsequently the shield 40. The shadow mask element 44 thus deflects the heavier particles away from the shield opening 41 and allows lighter particles to arrive at the substrate 13 to be deposited thereon. Without the shadow mask 44, the larger particulates that are present in the centre of the plume 33 might pass through the shield 40 and reach the substrate 13.

To optimally achieve the above effect, the shadow mask 44 blocks the passage opening 41 from the line of sight as seen from the origin of the plume 33. This is illustrated in FIG. 4, wherein the line-of-sight 33c is indicated by the dashed lines.

The shadow mask 44 in FIG. 4, shown enlarged in FIG. 5A, is mounted to the shield 44 via a connecting member 45 and is tapered in opposite directions, i.e., towards the target 21 and the passage opening 41. In particular, the front portion 44a of the shadow mask 44 is conical towards the target 21 to effectively deflect the particulates without causing the particles to bounce back. The back portion 44b of the shadow mask 44, which faces the passage opening 41, is shaped to create a low-pressure region downstream of the shadow mask 44 such that the plume particles, in particular the lighter particles, converge again after passing the shadow mask 44 (see also FIG. 3A).

In FIGS. 5B and 5C, the shadow mask 44 is teardrop shaped. The pointy end of the teardrop-shaped shadow mask 44 may be provided in the front end 44a (as in FIG. 5B) or in the back end 44b (as in FIG. 5C). In both cases shown, the opposite end is provided with a conical protrusion 44c. As the plume can propagate around the teardrop-shaped shadow mask 44 more smoothly, the pressure gradient around the shadow mask 44 can be improved in comparison with the shadow masks 44 of FIGS. 3A-5A.

The figures and the above description serve to illustrate specific embodiments of the invention and do not limit the scope of protection defined by the appended claims.

The present disclosure further includes the following embodiments:
1. Vapour deposition device for depositing a material layer onto a substrate, in particular a pulsed laser deposition device, wherein the vapour deposition device comprises:
a substrate holder comprising a substrate holding surface for holding a material deposition substrate thereon;
a target holder for holding a source of material to be deposited onto the substrate held on the substrate holding surface;
a vaporisation unit arranged for directing a vaporising beam to the target holder to vaporise, at a beam end where the vaporising beam hits the material source held by the target holder, a portion of the material source for the vaporised portion to be deposited onto the substrate held on the substrate holding surface,
   wherein the device is arranged to relatively move the beam end relative to the target holder in at least two nonparallel directions for scanning the beam end over an area of the material source, characterised in that the device is arranged to relatively move the target holder relative to the substrate holding surface in a direction which is non-perpendicular to the substrate holding surface.
2. Vapour deposition device according to embodiment 1, wherein the substrate holding surface is rotatable about a substrate axis, which extends therethrough and is perpendicular thereto, for axially rotating the substrate held on the substrate holding surface.
3. Vapour deposition device according to embodiment 2, wherein the vaporisation unit is arranged to translate the beam end towards and away from the substrate axis.
4. Vapour deposition device according to embodiment 1, 2 or 3, wherein the device is arranged to translate the target holder relative to the substrate holding surface in one or both of the two nonparallel directions.
5. Vapour deposition device according to any of the preceding embodiments, further comprising a shield member arranged between the target holder and the substrate holding surface, wherein the shield member is provided with a passage opening therethrough for the vaporised material to pass through the shield member and to be deposited onto the substrate held on the substrate holding surface.
6. Vapour deposition device according to embodiment 5, wherein the device is arranged to translate the beam end relative to the substrate holding surface in a direction which is non-perpendicular to the substrate holding surface, wherein the shield member is movable relative to the substrate holding surface along with the beam end for translating the passage opening synchronously with the beam end.
7. Vapour deposition device according to embodiment 5 or 6, wherein the passage opening is a pinhole.
8. Vapour deposition device according to embodiment 5, 6 or 7, further comprising a shield heating system arranged to maintain a temperature of the shield member within a first predetermined range.
9. Vapour deposition device according to any of the preceding embodiments, further comprising a holder heating system arranged to maintain a temperature of the substrate holder, in particular of the substrate holding surface, in a second predetermined range.
10. Vapour deposition device according to embodiments 8 and 9, wherein said temperature of the substrate holder exceeds said temperature of the shield member.
11. Vapour deposition device according to embodiment 8, 9 or 10, wherein the shield heating system comprises at least one heating element integrated into the shield member.
12. Vapour deposition device according to any of the embodiments 5-11, further comprising a shadow mask element arranged stationary relative to the shield member and between the passage opening and the target holder to deflect the vaporised material.
13. Vapour deposition device according to embodiment 12, wherein the shadow mask element is tapered towards the passage opening.
14. Vapour deposition device according to embodiment 13, wherein the shadow mask element is droplet shaped.
15. Vapour deposition device according to any of the preceding embodiments, wherein the substrate holder is arranged above the target holder.
16. Method of depositing a material layer onto a substrate, wherein the method comprises the steps of:
providing a material deposition substrate;
providing a source of material to be deposited onto the substrate;
directing a vaporising beam to the material source to vaporise, at a beam end where the vaporising beam hits the material source, a portion of the material source;
moving the beam end relative to the material source in at least two nonparallel directions for scanning the beam end over an area of the material source;
depositing the vaporised material onto the substrate;
moving the material source relative to the substrate in a direction which is non-perpendicular to the substrate.
17. Method according to embodiment 16, further comprising the step of axially rotating the substrate about a substrate axis which extends therethrough and is perpendicular to a surface of the substrate facing the material source.
18. Method according to embodiment 17, wherein the step of vaporising the portion of the material source comprises translating the beam end towards and away from the substrate axis.
19. Method according to embodiment 16, 17 or 18, further comprising the step of translating the material source relative to the substrate in one or both of the two nonparallel directions.
20. Method according to any of the preceding embodiments 16-19, further comprising the steps of:
providing a shield member between the material source and the substrate, wherein the shield member is provided with a passage opening therethrough for the vaporised material to pass through the shield member and be deposited onto the substrate;
translating the beam end relative to the substrate in a direction which is non-perpendicular to the substrate;
moving the shield member relative to the substrate along with the beam end for translating the passage opening synchronously with the beam end.
21. Method according to embodiment 20, further comprising the step of maintaining a temperature of the shield member within a first predetermined range.
22. Method according to embodiment 21, further comprising the step of maintaining a temperature of the substrate in a second predetermined range, wherein the temperature of the substrate exceeds the temperature of the shield member.
23. Method according to any of the preceding embodiments 16-22, comprising the step of providing a vapour deposition device according to any of the preceding embodiments 1-15, wherein the substrate is held on the substrate holding surface of the vapour deposition device, wherein the material source is held by the target holder of the vapour deposition device, and wherein the portion of the material source is vaporised using the vaporisation unit of the vapour deposition device.

1. A vapour deposition device for depositing a material layer onto a substrate, in particular a pulsed laser deposition device, wherein the vapour deposition device comprises:
a substrate holder comprising a substrate holding surface for holding a material deposition substrate thereon;
a target holder for holding a source of material to be deposited onto the substrate held on the substrate holding surface; and
a vaporisation unit arranged for directing a vaporising beam to the target holder to vaporise, at a beam end where the vaporising beam hits the material source held by the target holder, a portion of the material source for the vaporised portion to be deposited onto the substrate held on the substrate holding surface; and
wherein the device is arranged to relatively move the beam end relative to the target holder in at least two nonparallel directions for scanning the beam end over an area of the material source; and
wherein the device is arranged to relatively move the target holder relative to the substrate holding surface in a direction which is non-perpendicular to the substrate holding surface.

2. The vapour deposition device according to claim 1, wherein the substrate holding surface is rotatable about a substrate axis, which extends therethrough and is perpendicular thereto, for axially rotating the substrate held on the substrate holding surface.

3. The vapour deposition device according to claim 2, wherein the vaporisation unit is arranged to translate the beam end towards and away from the substrate axis.

4. The vapour deposition device according to claim 3, wherein the device is arranged to translate the target holder relative to the substrate holding surface in both of the two nonparallel directions.

5. The vapour deposition device according to claim 1, further comprising a shield member arranged between the target holder and the substrate holding surface, wherein the shield member is provided with a passage opening therethrough for the vaporised material to pass through the shield member and to be deposited onto the substrate held on the substrate holding surface.

6. The vapour deposition device according to claim 5, wherein the device is arranged to translate the beam end relative to the substrate holding surface in a direction which is non-perpendicular to the substrate holding surface, wherein the shield member is movable relative to the substrate holding surface along with the beam end for translating the passage opening synchronously with the beam end.

7. The vapour deposition device according to claim 6, wherein:
the substrate holding surface is rotatable about a substrate axis, which extends therethrough and is perpendicular thereto, for axially rotating the substrate held on the substrate holding surface;
the vaporisation unit is arranged to translate the beam end towards and away from the substrate axis; and
the passage opening is a pinhole.

8. The vapour deposition device according to claim 5, further comprising a shield heating system arranged to maintain a temperature of the shield member within a first predetermined range.

9. The vapour deposition device according to claim 1, further comprising a holder heating system arranged to maintain a temperature of the substrate holder, in particular of the substrate holding surface, in a second predetermined range;
wherein said temperature of the substrate holder exceeds said temperature of the shield member.

10. (canceled)

11. The vapour deposition device according to claim 8, wherein the shield heating system comprises at least one heating element integrated into the shield member.

12. The vapour deposition device according to claim 5, further comprising a shadow mask element arranged stationary relative to the shield member and between the passage opening and the target holder to deflect the vaporised material.

13. The vapour deposition device according to claim 12, wherein the shadow mask element is tapered towards the passage opening.

14. The vapour deposition device according to claim 13, wherein the shadow mask element is droplet shaped.

15. The vapour deposition device according to claim 1, wherein the substrate holder is arranged above the target holder.

16. A method of depositing a material layer onto a substrate, wherein the method comprises the steps of:
providing a material deposition substrate;
providing a source of material to be deposited onto the substrate;
directing a vaporising beam to the material source to vaporise, at a beam end where the vaporising beam hits the material source, a portion of the material source;
moving the beam end relative to the material source in at least two nonparallel directions for scanning the beam end over an area of the material source;
depositing the vaporised material onto the substrate; and
moving the material source relative to the substrate in a direction which is non-perpendicular to the substrate.

17. The method according to claim 16, further comprising the step of axially rotating the substrate about a substrate axis which extends therethrough and is perpendicular to a surface of the substrate facing the material source.

18. The method according to claim 17, wherein the step of vaporising the portion of the material source comprises translating the beam end towards and away from the substrate axis.

19. The method according to claim 16, further comprising the step of translating the material source relative to the substrate in one or both of the two nonparallel directions.

20. The method according to claim 16, further comprising the steps of:
providing a shield member between the material source and the substrate, wherein the shield member is provided with a passage opening therethrough for the vaporised material to pass through the shield member and be deposited onto the substrate;
translating the beam end relative to the substrate in a direction which is non-perpendicular to the substrate; and
moving the shield member relative to the substrate along with the beam end for translating the passage opening synchronously with the beam end.

21. The method according to claim 20, further comprising:
the step of maintaining a temperature of the shield member within a first predetermined range; and
the step of maintaining a temperature of the substrate in a second predetermined range, wherein the temperature of the substrate exceeds the temperature of the shield member.

22. (canceled)

23. (canceled)
